(19) United States
(12) Patent Application Publication
(10) Pub. No.: US 2022/0088715 A1
(43) Pub. Date: Mar. 24, 2022

(54) METHOD FOR MANUFACTURING DEPOSITION MASK

(71) Applicant: SAKAI DISPLAY PRODUCTS CORPORATION, Sakai-shi, Osaka (JP)

(72) Inventors: SUSUMU SAKIO, Sakai-shi, Osaka (JP); KATSUHIKO KISHIMOTO, Sakai-shi, Osaka (JP)

(21) Appl. No.: 17/600,080

(22) PCT Filed: Apr. 1, 2019
(86) PCT No.: PCT/JP2019/014508

§ 371 Date: Sep. 29, 2021

(51) Int. Cl. B23K 26/36; C23C 14/04; G06F 30/23

(52) U.S. Cl. CPC B23K 26/36; H01L 51/0011; G06F 30/23; C23C 14/042

(57) ABSTRACT

A method for manufacturing a deposition mask having a plurality of openings arranged in a matrix pattern in an active region formation portion of a mask base, which is fixed to a frame while being tensioned, the method including: a step A of preparing a mask base of an initial state fixed to a frame while being tensioned in a predetermined condition so as to define an xy plane; a step B of preparing target coordinate data that identifies a position of each of the plurality of openings in the xy plane; a step C of predicting, for each of the plurality of openings, an amount of displacement from the target coordinate data caused by the formation of the openings to generate such correction data that reduces the amount of displacement; and a step D of forming each of the plurality of openings at a position that is identified based on the target coordinate data and the correction data, wherein: in the step C, the correction data for each of the plurality of openings is associated with an order in which the plurality of openings are formed; and in the step D, the plurality of openings are formed in the order.

### TECHNICAL FIELD

The present invention relates to a method for manufacturing a deposition mask, and particularly to a method for manufacturing a deposition mask that is desirably used in mass production of high-definition organic EL (Electro Luminescence) display devices. A deposition mask refers to a mask that is used in thin film deposition techniques (including, for example, Physical Vapor Deposition (PVD) and Chemical Vapor Deposition (CVD)). The description below is directed to an example of a vacuum deposition method, a type of PVD.

### BACKGROUND ART

In recent years, organic EL display devices have been commercialized. With small- and medium-sized organic EL display devices that are currently being mass-produced, an organic EL layer is formed primarily by using a vacuum deposition method. An organic EL layer includes, for example, a hole transport layer, an electron transport layer, and an organic light-emitting layer disposed therebetween. A hole transport layer can serve also as an organic light-emitting layer. A layer formed of an organic material that at least includes an organic light-emitting layer and an electron transport layer will be referred to as an organic EL layer.

An organic EL display device includes, for each pixel, at least one organic EL device (Organic Light Emitting Diode: OLED), and at least one TFT (Thin Film Transistor) that controls the current supplied to each OLED. Hereinafter, an organic EL display device will be referred to as an OLED display device. An OLED display device having a switching device such as a TFT for each OLED is referred to as an active matrix-type OLED display device. A substrate on which TFTs and OLEDs are formed will be referred to as a device substrate. A driving circuit including TFTs is referred to as a backplane circuit (or simply as a “backplane”), and OLEDs are formed on a backplane.

With an organic EL display device capable of producing color display, a single color display pixel is composed of an R pixel, a G pixel and a B pixel, for example. The pixels of different colors forming a color display pixel may be referred to also as primary color pixels. A pixel as used in the present specification may be referred to as a “dot”, and a color display pixel as a “pixel”. For example, ppi (pixel per inch), which represents resolution, represents the number of “pixels” included in one inch.

Note that a single color display pixel is composed of three pixels or different colors, the three pixels of different colors may differ from each other in terms of shape and size. For example, a blue pixel, which has a lower emission efficiency, may be made larger, and a green pixel, which has a higher emission efficiency, may be made smaller. Alternatively, a single color display pixel may be composed of one red pixel, one green pixel and two blue pixels. The pixel array may be a stripe array or a delta array, and may be any of various arrays known in the art.

The organic EL layer is formed by a vacuum deposition method using a deposition mask prepared for each color. In addition to the organic EL layer, an electrode layer (e.g., a cathode layer) formed on the organic EL layer can also be formed by a sputtering method, for example, using a deposition mask. An electrode layer (e.g., an anode layer) formed under the organic EL layer may be formed by photolithography because the organic EL layer is never exposed to the developing solution.

A metal mask (which may be referred to as Fine Metal Mask: FMM) including a metal layer (metal plate) with a plurality of openings arranged in a predetermined pattern has been used as a deposition mask (e.g., Patent Document No. 1). In order to accommodate higher definitions of OLED display devices, a deposition mask that includes a resin layer and a magnetic metal layer stacked together (hereinafter referred to as a “stack mask”) has been proposed in the art, which is capable of forming patterns of higher definitions than a metal mask (e.g., Patent Document Nos. 2, 3).

In the present specification, a member in which openings (through holes through which the substance to be deposited passes) of a deposition mask are formed is referred to as a mask base. With a metal mask, the metal layer (typically, the magnetic metal layer) is the mask base, and with a stacked mask, a resin layer, in the stack of a resin layer and a magnetic metal layer, is the mask base. A portion of the deposition mask that comes into close contact with the active region (referred to also as the “device formation region” or the “display region”) of a device substrate (e.g., a substrate at the stage where a backplane has been formed) to be deposited will be referred to as an active region formation portion.

### CITATION LIST

### Patent Literature

Patent Document No. 1: Japanese Laid-Open Patent Publication No. 2006-188748

Patent Document No. 2: Japanese Ladd-Open Patent Publication No. 2017-82313

Patent Document No. 3: Japanese Laid-Open Patent Publication No. 2015-10270

Patent Document No. 4: Japanese Patent No. 4173329 (U.S. Pat. No. 6,773,854)

### SUMMARY OF INVENTION

### Technical Problem

With both a metal mask and a stack mask, the mask base is tensioned in order to increase the flatness of the active region formation portion. This is because if the flatness of the active region formation portion is low, i.e., if there is slack in the mask base of the active region formation portion, a gap is produced between the active region formation portion and the surface of the device substrate, thus failing to successfully deposit into a predetermined shape.

However, according to a study by the present inventors, when openings are formed in a tensioned mask base, the direction and magnitude distribution of strain (stress) (which may be referred to simply as the “strain distribution (stress distribution)”) in the mask base may change due to the formation of the openings, thereby displacing (shifting) the positions of the openings.

Since the mask base is tensioned (being under an in-plane tension in the outward direction), there is a strain (stress) in the mask base. This strain (stress) is a function of the position in the mask base. In other words, the direction and the magnitude of the strain (stress) vary depending on the position in the mask base. The strain (stress) distribution of the mask base changes each time an opening is formed in the mask base. Therefore, the eventual positional precision of openings is dependent also on the order in which the openings are formed. This is particularly problematic when forming an opening pattern with a high definition of over 200 ppi, for example.

Moreover, with a deposition mask accommodating a plurality of active regions, i.e., a deposition mask used for a mother substrate from which multiple OLED display devices are to be obtained, the strain (stress) distribution in the mask base varies depending on the position of the active region formation portion, thereby resulting in a problem as described above.

For example, Patent Document No. 4 discloses, for a method for producing a shadow mask for particle beams, predicting the strain to be caused by forming a plurality of openings of a predetermined pattern in a mask base (unprocessed product), and forming a plurality of openings of a predetermined pattern such that a strain opposite to the predicted strain is generated.

However, Patent Document No. 4 fails to solve the problem described above because it does not take into consideration the order in which a plurality of openings are formed, i.e., change in the strain in the process of forming the plurality of openings.

It also fails to accommodate variations in the thickness of the mask base (variations between a plurality of mask bases and variations between different positions in each mask base).

The present invention has been made to solve at least one of the problems described above, and an object of the present invention is to suppress a decrease in positional precision due to positional displacement of openings due to change in the strain (stress) distribution of the mask base in the process of manufacturing a deposition mask having a tensioned mask base (e.g., a metal layer of a metal mask or a resin layer of a stack mask).

### Solution to Problem

Solutions set forth in the following items may be provided according to an embodiment of the present invention.

### Item 1

A method for manufacturing a deposition mask, the deposition mask including a frame, a mask base fixed to the frame while being tensioned, and a plurality of openings provided in an active region formation portion of the mask base and arranged in a matrix pattern of m rows and n columns, the method including:

a step A of preparing a mask base of an initial state fixed to the frame while being tensioned in a predetermined condition so as to define an xy plane;

a step B of preparing target coordinate data that identifies a position of each of the plurality of openings in the xy plane;

a step C of predicting, for each of the plurality of openings, an amount of displacement from the target coordinate data caused by the formation of the openings to generate such correction data that reduces the amount of displacement; and

a step D of forming each of the plurality of openings at a position that is identified based on the target coordinate data and the correction data, wherein:

in the step C, the correction data for each of the plurality of openings is associated with an order in which the plurality of openings are formed; and

in the step D, the plurality of openings are formed in the order.

### Item 2

The manufacturing method according to Item 1, wherein:

the step C includes a step CS of obtaining a strain distribution of the entire mask base when an opening is formed in accordance with the order in which the plurality of openings are formed by a simulation using a finite element method so as to predict an amount of displacement for each of the plurality of openings based on the strain distribution and generate the correction data; and

the step CS includes:
a step CS1 of obtaining an amount of displacement D1(k) at a position on the mask base where a k^{th} opening should be formed based on the strain distribution of the entire mask base immediately before forming the k^{th} opening;
a step CS2 of obtaining an amount of displacement D2(k) at the position on the mask base where the k^{th} opening should be formed based on the strain distribution of the entire mask base after all of the plurality of openings are formed; and
a step CS3 of obtaining correction data C(k) for the k^{th} opening from D1(k) and D2(k).

### Item 3

The manufacturing method according to Item 2, wherein in the step CS, initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state are given in advance.

### Item 4

The manufacturing method according to Item 2, wherein:

the step C includes, in the step CS, a step CSP of obtaining a distribution in the xy plane of at least Lz⁰ among initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state; and

the step CSP further includes:

a step CSP1 of obtaining the strain distribution of the entire mask base when a plurality of depressions whose depth d is 40% or less of a thickness of the mask base are formed so as to correspond to the plurality of openings in accordance with the order in which the plurality of openings are formed by a simulation using a finite element method;

a step CSP2 of measuring positions of the depressions formed;

a step CSP3 of comparing an amount of displacement D^{P} of each of the depressions obtained based on the strain distribution obtained in the step CSP1 with an amount of displacement D^{M} of each of the depressions obtained from the positions of the depressions obtained in the step CSP2; and

a step CSP4 of obtaining a distribution in the xy plane of Lz⁰, among the initial parameters, so as to reduce a difference between the amount of displacement D^{P} and the amount of displacement D^{M} based on a comparison result obtained in the step CSP3.

### Item 5

The manufacturing method according to Item 2 or 4, wherein:

the step C, in the step CS, includes a step CSD of obtaining at least one of parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state; and

the step CSD further includes:

a step CSD1 of obtaining the strain distribution of the entire mask base when at least one dummy opening is formed outside the active region formation portion by a simulation using a finite element method;

a step CSD2 of measuring a position of the at least one dummy opening formed;

a step CSD3 of comparing an amount of displacement D^{Pd} of the at least one dummy opening obtained based on the strain distribution obtained in the step CSD1 with an amount of displacement D^{Md} of the at least one dummy opening obtained from the position of the at least one dummy opening obtained in the step CSD2; and

a step CSD4 of obtaining at least one of the initial parameters so as to reduce a difference between the amount of displacement D^{Pd} and the amount of displacement D^{Md} based on a comparison result obtained in the step CSD3.

### Item 6

The manufacturing method according to any one of Items 1 to 5, wherein the mask base is formed of a magnetic metal layer.

### Item 7

The manufacturing method according to any one of Items 1 to 5, wherein the mask base is formed of a resin layer.

### Item 8

The manufacturing method according to Item 7, wherein the deposition mask further includes a magnetic metal layer having at least one through hole through which the plurality of openings formed in the resin layer are exposed.

### Advantageous Effects of Invention

According to an embodiment of the present invention, it is possible to suppress a decrease in positional precision due to positional displacement of openings caused by change in the strain (stress) distribution of the mask base in the process of manufacturing a deposition mask having a tensioned mask base, for example.

### BRIEF DESCRIPTION OF DRAWINGS

FIG. 1 is a schematic plan view of a deposition mask 100A manufactured by a manufacturing method according to an embodiment of the present invention.

FIG. 2 is a schematic plan view of a portion 10p of an active region formation portion 10A the deposition mask 100A.

FIG. 3 is a schematic cross-sectional view of a deposition mask 100B manufactured by a manufacturing method according to an embodiment the present invention, showing a cross section taken along line 3A-3A of FIG. 3.

FIG. 4 is a schematic plan view of the deposition mask 100B.

FIG. 5 is a schematic diagram illustrating the principle for obtaining the amount of positional displacement of openings due to change in the strain distribution caused by the formation of openings in the mask base in a simulation in a manufacturing method according to an embodiment of the present invention.

FIG. 6 is a schematic diagram showing an exemplary result of obtaining the amount or positional displacement of openings due to change in the strain distribution caused by the formation of openings in the mask base in a simulation in a manufacturing method according to an embodiment or the present invention.

### DESCRIPTION OF EMBODIMENTS

A method for manufacturing a deposition mask according to an embodiment of the present invention will now be described with reference to the drawings. Note that the embodiment of the present invention is not limited to the embodiment illustrated herein.

First, an example of a deposition mask that is desirably manufactured by a manufacturing method according to an embodiment of the present invention. The manufacturing method according to an embodiment of the present invention is not limited to a deposition mask illustrated below, but is widely applicable to the manufacture of deposition masks that are manufactured by forming openings in a tensioned mask base as described in Patent Document Nos. 1 to 3, for example. The entire disclosures of Patent Document Nos. 1 to 3 are incorporated herein by reference.

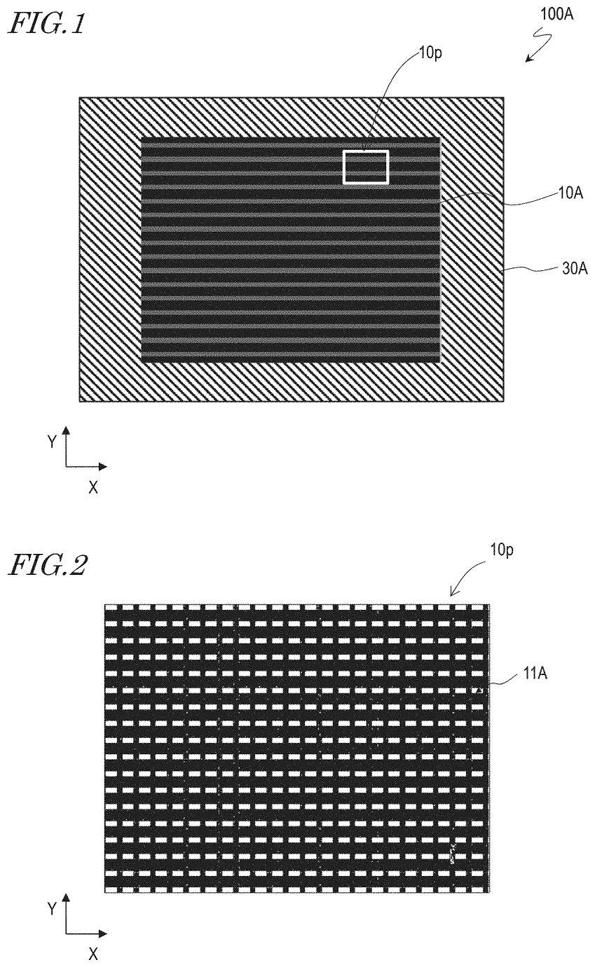

Referring to FIG. 1 and FIG. 2, a structure of a deposition mask 100A that is desirably manufactured by a manufacturing method according to an embodiment of the present invention will be described. FIG. 1 is a schematic plan view of the deposition mask 100A, and FIG. 2 is a schematic plan view of a portion 10p of an active region formation portion 10A of the deposition mask 100A. The deposition mask 100A is a metal mask.

The deposition mask 100A includes a magnetic metal layer 10A and a frame 30A as shown in FIG. 1. The magnetic metal layer 10A includes a plurality of openings 11A. The plurality of openings 11A are formed in size, shape and position corresponding to a plurality of pixels to be formed on the device substrate (backplane). The frame 30A is frame-shaped and is fixed to the periphery of a magnetic metal layer 20A. The frame 30A is formed of invar, for example.

In the example shown in FIG. 2, the plurality of openings 11A are disposed in a matrix pattern. The size, shape, and position of the openings 11A may vary depending on the emission color of the organic EL layer to be formed. The mask member of the deposition mask 100A is the magnetic metal layer 10A. For the magnetic metal layer 10A, it is preferred to use a magnetic metal material having a small linear thermal expansion αM (specifically, less than 6 ppm/° C.). For example, an Fe—Ni-based alloy (invar), an Fe—Ni—Co-based alloy, or the like, can be preferably used. The openings 11A can be formed by a laser process, for example.

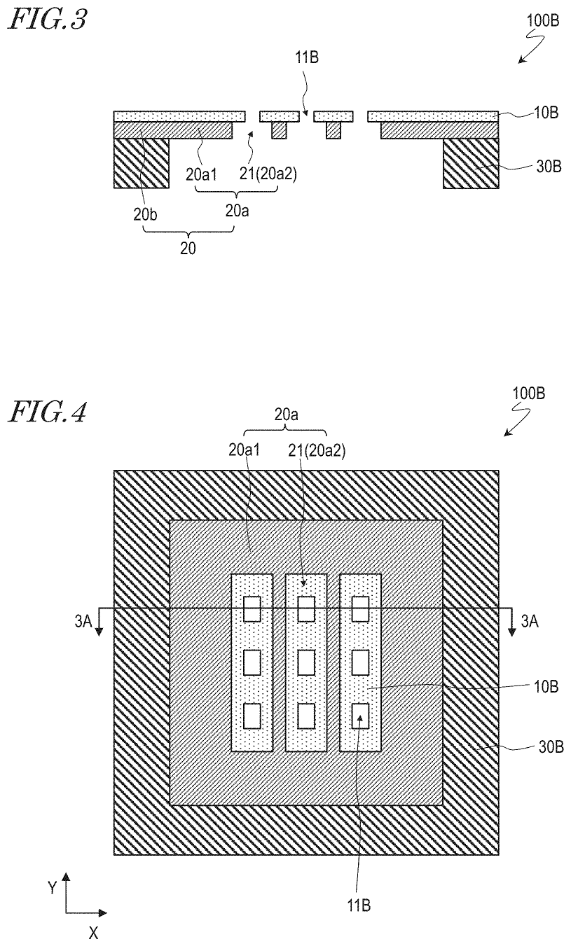

Next, referring to FIG. 3 and FIG. 4, a structure of a deposition mask 100B that is desirably manufactured by a manufacturing method according to an embodiment of the present invention will be described. The deposition mask 100B is stacked. FIG. 3 and FIG. 4 are a cross-sectional view and a plan view, respectively, schematically showing the deposition mask 100B. FIG. 3 shows a cross section taken along line 3A-3A of FIG. 4. Note that it is understood that FIG. 3 and FIG. 4 schematically show an example of the deposition mask 100B, and that the size, number, positional relationship, length ratio, etc., of the components are not limited to those of the illustrated example. This similarly applies to other figures to be discussed below.

As shown in FIG. 3 and FIG. 4, the deposition mask 100B includes the resin layer 10B, a magnetic metal layer 20B and a frame 30B. When performing a vapor deposition step using the deposition mask 100B, the deposition mask 100B is disposed so that the magnetic metal layer 20B is located on the side of the vapor deposition source and the resin layer 10B is located on the side of the vapor deposition object (the device substrate with the backplane formed thereon).

The resin layer 10B includes a plurality of openings 11B. The plurality of openings 11B are formed in size, shape and position corresponding to a plurality of pixels to be formed on the device substrate (backplane). In the example shown in FIG. 4, the plurality of openings 11B are disposed in a matrix pattern. The size, shape and position of the openings 11B may vary depending on the emission color of the organic EL layer to be formed. The mask member of the deposition mask 100B is the resin layer 10B.

For example, polyimide can be preferably used as the material of the resin layer 10B. Polyimide has a small thermal expansion coefficient and has good strength, chemical resistance and heat resistance. Another resin material such as polyethylene terephthalate (PET) may be used as the material of the resin layer 10B.

There is no particular limitation on the thickness of the resin layer 10B. Note however that if the resin layer 10B is too thick, a portion of the vapor deposition film may be formed to be thinner than the desired thickness (referred to as “shadowing”). In order to suppress the occurrence of shadowing, it is preferred that the thickness of the resin layer 10B is 25 μm or less. In view of the strength and cleaning resistance of the resin layer 10B itself, it is preferred that the thickness of the resin layer 10B is 3 μm or more.

The magnetic metal layer 20B is formed on the resin layer 10B. The magnetic metal layer 20B is formed on the resin layer 10B by a plating method, for example, as will be described below. The magnetic metal layer 20B is in close contact with the resin layer 10B. The magnetic metal layer 20B includes a mask portion 20a and a peripheral portion 20b disposed so as to surround the mask portion 20a. The mask portion 20a refers to the magnetic metal layer 20B of the active region formation portion.

The mask portion 20a of the magnetic metal layer 20B has a plurality of through holes (slits) 21 through which a plurality of openings 11B of the resin layer 10B are exposed. In the example shown in FIG. 4, a plurality of through holes 21, extending in the column direction, are arranged next to each other in the row direction. As seen from the direction normal to the deposition mask 100B, each through hole 21 has a size larger than each opening 11B of the resin layer 10, and at least one (herein, a plurality of) openings 11B are located in each through hole 21.

The magnetic metal layer 20B is formed by electroless plating or electrolytic plating, for example. It is preferably a nickel (Ni) plating layer or a nickel alloy plating layer. It is preferred to form the resin layer 10B with polyimide to match the thermal expansion coefficient of the magnetic metal layer 20B with the resin layer 10B.

There is no particular limitation on the thickness of the magnetic metal layer 20B. Note however that if the magnetic metal layer 20B is too thick, the magnetic metal layer 20B may bend under its own weight or shadowing may occur. In order to suppress the bending under its own weight and the occurrence of shadowing, the thickness of the magnetic metal layer 20B is preferably 100 μm or less, and more preferably 25 μm or less. If the magnetic metal layer 20B is too thin, it may lower the suction force from the magnetic chuck in the vapor deposition step to be described below, and produce a gap between the deposition mask 100B and the work. There is also a risk of breakage or deformation, making handling difficult. Therefore, the thickness of the magnetic metal layer 20B is preferably 5 μm or more.

The frame 30B is frame-shaped and is fixed to the peripheral portion 20b of the magnetic metal layer 20B. That is, a region of the magnetic metal layer 20B that does not overlap with the frame 30B is the mask portion 20a, and a region thereof that overlaps with the frame 30B is the peripheral portion 20b. The frame 30B is formed of a metal material, for example. The frame 30B is preferably a magnetic metal material having a small linear thermal expansion αM (specifically, less than 6 ppm/° C.). For example, it is preferably an Fe—Ni-based alloy (invar), an Fe—Nd—Co-based alloy, or the like.

With the deposition mask 100B, as shown in FIG. 3, the magnetic metal layer 20B is entirely attached to the resin layer 10B. The resin layer 10B and the magnetic metal layer 20B are receiving a tension in the layer plane direction from the frame 30B. As will be described below, in the tensioning step, the resin layer 10B and the magnetic metal layer 20B are fixed to the frame 30B while being tensioned in a predetermined layer plane direction by an extension device (or an extension and welding device having a welding function).

In the method for manufacturing the deposition mask 100B, openings 11B are formed in regions of the resin layer 10B that are exposed through the through holes 21 of the magnetic metal layer 20B.

The openings 11 can be formed by a laser process, for example. A pulsed laser is used for the laser process. Here, the third harmonic of a YAG laser is used, and a laser beam L2 having a wavelength of 355 nm is irradiated onto a predetermined region of the resin layer 10. In this process, the workpiece structure including the frame 30, the magnetic metal layer 20 and the resin layer 10) is flipped upside down so that the irradiation direction of the laser beam L2 is the downward direction. The energy density of the laser beam L2 is 0.5 J/cm², for example. The laser process is performed by a plurality of shots while focusing the laser beam L2 on the surface of the resin layer 10. The number of shots is determined based on the thickness of the resin layer 10. The shot frequency is set to 60 Hz, for example.

Note that there is no particular limitation on the conditions of the laser process, and the conditions are selected appropriately so that it is possible to machine the resin layer 10B. For example, a laser beam having a large beam diameter may be prepared, and the laser beam may be irradiated through a photomask having openings corresponding to 50×50 or 100×100 openings 11B, for example, thereby forming the openings 11 block by block.

If a plurality of openings are formed successively by, for example, irradiating a laser beam onto a mask base being tensioned, as described above, the strain (stress) distribution in the mask base may vary due to the formation of the openings, thereby displacing (shifting) the positions of the openings. This is a common problem among methods for manufacturing a metal mask, a stack mask or a resin mask (i.e., a stack mask with the magnetic metal layer omitted) described above.

In order to solve this problem, a method for manufacturing a deposition mask according to an embodiment of the present invention includes the following steps.

Step A: preparing a mask base of an initial state fixed to a frame while being tensioned in a predetermined condition so as to define an xy plane. The mask base refers to the magnetic metal layer of the metal mask or the resin layer of the stack mask or the resin mask, in which a plurality of openings are formed while being tensioned, and the initial state refers to a state where no opening has been formed while being tensioned.

Step B: preparing target coordinate data that identifies the position of each of the plurality of openings in the xy plane.

Step C: predicting, for each of the plurality of openings, an amount of displacement from the target coordinate data caused by the formation of the openings to generate such correction data that reduces the amount of displacement. In this process, correction data for each of the plurality of openings is associated with the order in which the plurality of openings are formed. That is, since the strain distribution across the entire mask base changes depending on the order in which openings are formed, correction data is generated taking this into consideration.

Step D: forming each of the plurality of openings at a position that is identified based on the target coordinate data and the correction data. The order in this process is the same as the order that is taken into consideration in the step C.

The step C may be performed by a known method of simulating the strain (stress) distribution, such as the finite element method or the boundary element method. For example, it may be performed using a commercially available finite element method program, such as ANSYS Shell181 (ANSYS is a registered trademark of Ansys, Inc.).

For example, the step C includes a step CS of obtaining the strain distribution of the entire mask base when an opening is formed in accordance with the order in which the plurality of openings are formed by a simulation using a finite element method so as to predict the amount of displacement for each of the plurality of openings based on the strain distribution and generate the correction data.

The step CS includes, as schematically shown in FIG. 5, for example: a step CS1 of obtaining the amount of displacement D1(k) at a position on the mask base where a k^{th} opening should be formed based on the strain distribution of the entire mask base immediately before forming the k^{th} opening; a step CS2 of obtaining the amount of displacement D2(k) at the position on the mask base where the k^{th} opening should be formed based on the strain distribution of the entire mask base after all of the plurality of openings are formed; and a step CS3 of obtaining correction data C(k) for the k^{th} opening from D1(k) and D2(k). As can be seen from FIG. 5, it can be seen that the amounts of displacement D1(k) and D2(k) are expressed as vectors, and the correction data C(k) can be D1(k)-D2(k) so as to cancel out D2(k)-D1(k).

Next, an example where an embodiment of the present invention is applied to a method for manufacturing the deposition mask 100A shown in FIG. 1 and. FIG. 2 will be described.

The material of the mask base is invar, and parameters used in the simulation are shown below.

Size of mask base Lx⁰, Ly⁰, Lz⁰: 410 mm, 330 mm, 0.01 mm

Young's modulus Yx⁰, Yy⁰: 1.41×10⁵ MPa

Poisson's ratio Pxy⁰: 0.29 (the modulus of rigidity Gxy⁰ is obtained from the Young's modulus and the Poisson's ratio)

Tension Tx⁰, Ty⁰: forcibly displaced by 0.114% in the X direction and 0.037% in the Y direction.

Size of opening: 0.64 mm (X)×0.3 mm (Y)

Arrangement pitch of openings: 0.94 mm (X, Y)

Number of openings: 351 (X)×266 (Y)=93,366

The number of elements was 1,599,276, and the element type was ANSYS Shell181.

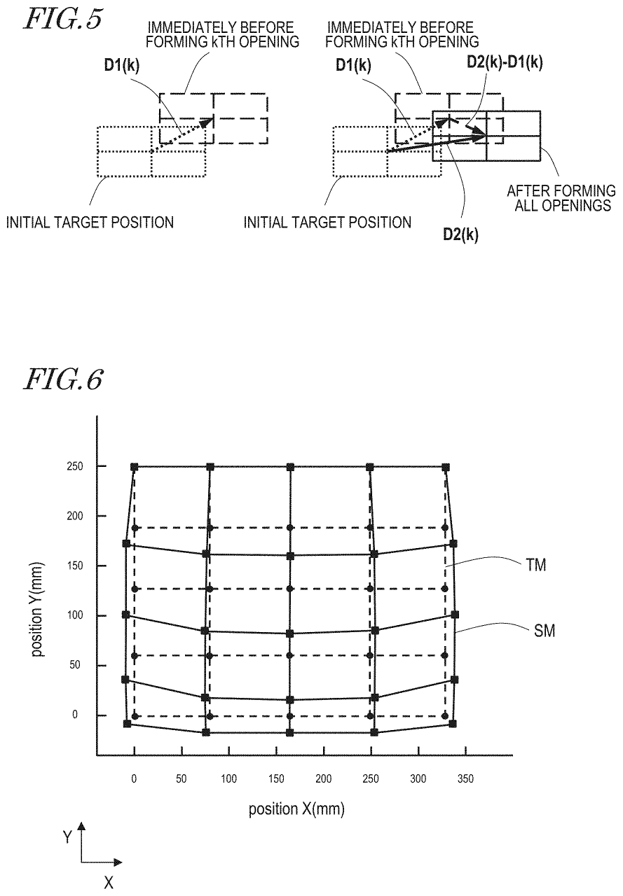

FIG. 6 a schematic diagram showing an exemplary result of obtaining, in the simulation described above, the amount of positional displacement of openings due to change in the strain distribution caused by the formation of openings in the mask base. Black circles (broken lines) represent the target coordinate data (TM), and black squares (solid lines) represent the simulation result (SM).

Openings were formed for each row starting from the lowermost row (1st row) to the uppermost row (266th row) as shown in FIG. 6, and every time a row of openings were formed, the strain distribution of the entire mask base was calculated by the finite element method to thereby obtain the amount of displacement of the openings. The black squares represent the amount of displacement of the openings after all the openings are formed. For the sake of simplicity, a result obtained by multiplying the amount of displacement by 1000 is shown for five openings for each row.

As can be seen from FIG. 6, the positional precision of openings lowers because of displacement from the target coordinate data caused by the formation of openings. By making a correction so as to cancel out the amount of displacement, it is possible to improve the positional precision of openings.

Note however that it may not be possible, with a single parameter (the parameter of the initial state described above), to represent the mask base over the entirety thereof. For a fine metal mask (FMM) or a stack mask having a high definition, a thin mask base is used, and a non-uniform distribution may occur in thickness, and the non-uniform distribution often varies for each mask base.

If there are mask base thickness variations (variations between mask bases and variations between positions within an individual mask base), it is preferred to form depressions whose depth is, for example, 40% or less (e.g., 20%) of the thickness of the mask base (100% means running throughout the thickness) at positions corresponding to all the openings, for example, instead of forming openings running through the thickness, to measure the positions of the depressions formed in the xy plane, and to optimize Lne distribution (variations) of the thickness Lz, among the parameters of the mask base used in the simulation (Young's modulus Yx, Yy, modulus of rigidity Gxy, Poisson's ratio Pxy, density ρ, tension Tx, Ty, size Lx, Ly, Lz), in accordance with the measurement results.

Specifically, for example, the step C may include, in the step CS, a step CSP of obtaining the distribution in the xy plane of at least Lz⁰ among the initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state, wherein the step CSP further includes: a step CSP1 of obtaining the strain distribution of the entire mask base when a plurality of depressions whose depth d is 40% or less of the thickness of the mask base are formed so as to correspond to the plurality of openings in accordance with the order in which the plurality of openings are formed by a simulation using a finite element method; a step CSP2 of measuring the positions of the depressions formed; and a step CSP3 of comparing the amount of displacement D^{P} of of the depressions obtained based on the strain distribution obtained in the step CSP1 with the amount of displacement D^{M} of each of the depressions obtained from the positions of the depressions obtained in the step CSP2; and a step CSP4 of obtaining the distribution in the xy plane of Lz⁰, among the initial parameters, so as to reduce the difference between the amount of displacement D^{P} and the amount of displacement D^{M} based on the comparison result obtained in the step CSP3.

The plurality of openings are preferably formed in the order described in WO/2019/043866 of the same applicant. If the plurality of openings are formed in the order described in WO/2019/043866, it is possible to reduce the amount of displacement caused by the formation of the openings. As a result, it is possible to further increase the positional precision of the openings. The entire disclosure of WO/2019/043866 is incorporated herein by reference.

A stress-relief opening may be provided outside the active region as described in U.S. Pat. No. 5,763,121. The parameters of the mask base may be obtained by using the stress-relief opening.

For example, the step C may include, in the step CS, a step CSD of obtaining at least one of the initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state, wherein the step CSD further includes: a step CSD1 of obtaining the strain distribution of the entire mask base when at least one dummy opening is formed outside an active region formation portion by a simulation using a finite element method; a step CSD2 of measuring the position of the at least one dummy opening formed; a step CSD3 of comparing the amount of displacement D^{Pd} of the at least one dummy opening obtained based on the strain distribution obtained in the step CSD1 with the amount of displacement D^{Md} of the at least one dummy opening obtained from the position of the at least one dummy opening obtained in the step CSD2; and a step CSD4 of obtaining at least one of the initial parameters so as to reduce the difference between the amount of displacement D^{Pd} and the amount of displacement D^{Md} based on the comparison result obtained in the step CSD3.

In the simulation example described above, openings are formed row by row, and the strain distribution of the entire mask base is calculated by the finite element method to obtain the amount of displacement of the openings for each row. It is understood that openings may be formed one by one, and the strain distribution of the entire mask base may be calculated by the finite element method every time an opening is formed to obtain the amount of displacement of the openings. While the number of openings to be formed at a time and the order in which the openings are formed are preferably the same as those when the openings are actually formed in the mask base, the process may be made simpler or easier considering the load of the simulation (the calculation time). The number of elemental divisions can be set appropriately in accordance with the size of the mask base and the precision required. The shape of the opening is not limited to a rectangular shape as illustrated, but may be changed as necessary to a square, a circle, an ellipse, etc.

The method for manufacturing a deposition mask according to an embodiment of the present invention can be performed by, for example, using a known laser processor. For example, the laser processor includes a stage capable of holding a mask base at a predetermined position so as to define the xy plane and transporting the mask base in the xy plane, a laser irradiation device for irradiating a laser beam onto a designated spot of the mask base on the stage, and a computer for controlling the laser irradiation device and the stage.

The laser irradiation device may include a laser light source that emits a laser beam, an optical system that directs a laser beam in a predetermined direction and/or shapes the beam profile, etc. The computer sends a command to the laser irradiation device and the stage (e.g., adjusting the pulse width, the pulse interval and the number of pulses of the pulsed laser) that laser beams of predetermined energy densities are irradiated in predetermined order and at predetermined positions. The computer further includes, for example, a storage device storing therein a program (e.g., ANSYS Shell181) for obtaining the strain distribution (stress distribution) by the finite element method described above, and performs the simulation described above on processor using the input data (e.g., target coordinate data of openings, the size and shape of openings, the order in which openings are formed, the parameters of the mask base, etc.) to send a command that identifies positions at which openings are formed to the laser irradiation device and the stage based on the target coordinate data and the correction data.

### INDUSTRIAL APPLICABILITY

An embodiment of the present invention can suitably be used for manufacturing a deposition mask used for manufacturing an organic EL device, for example.

### REFERENCE SIGNS LIST

10 Resin layer

11A, 11B Opening

20B Magnetic metal layer

20a Mask portion

20a1 Solid portion

20a2 Non-solid portion

20b Peripheral portion

100A, 100B Deposition mask

1-8. (canceled)

9. A method for manufacturing a deposition mask, the deposition mask including a frame, a mask base fixed to the frame while being tensioned, and a plurality of openings provided in an active region formation portion of the mask base and arranged in a matrix pattern of m rows and n columns, the method comprising:
a step A of preparing a mask base of an initial state fixed to the frame while being tensioned in a predetermined condition so as to define an xy plane;
a step B of preparing target coordinate data that identifies a position of each of the plurality of openings in the xy plane;
a step C of predicting, for each of the plurality of openings, an amount of displacement from the target coordinate data caused by the formation of the openings to generate such correction data that reduces the amount of displacement; and
a step D of forming each of the plurality of openings at a position that is identified based on the target coordinate data and the correction data, wherein:
in the step C, the correction data for each of the plurality of openings is associated with an order in which the plurality of openings are formed; and
in the step D, the plurality of openings are formed in the order.

10. The manufacturing method according to claim 9, wherein:
the step C includes a step CS of obtaining a strain distribution of the entire mask base when an opening is formed in accordance with the order in which the plurality of openings are formed by a simulation using a finite element method so as to predict an amount of displacement for each of the plurality of openings based on the strain distribution and generate the correction data; and
the step CS includes:
a step CS1 of obtaining an amount of displacement D1(k) at a position on the mask base where a k^{th} opening should be formed based on the strain distribution of the entire mask base immediately before forming the k^{th} opening;
a step CS2 of obtaining an amount of displacement D2(k) at the position on the mask base where the k^{th} opening should be formed based on the strain distribution of the entire mask base after all of the plurality of openings are formed; and
a step CS3 of obtaining correction data C(k) for the k^{th} opening from D1(k) and D2(k).

11. The manufacturing method according to claim 10, wherein in the step CS, initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state are given in advance.

12. The manufacturing method according to claim 10, wherein:
the step C includes, in the step CS, a step CSP of obtaining a distribution in the xy plane of at least Lz⁰ among initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state; and
the step CSP further includes:
a step CSP1 of obtaining the strain distribution of the entire mask base when a plurality of depressions whose depth d is 40% or less of a thickness of the mask base are formed so as to correspond to the plurality of openings in accordance with the order in which the plurality of openings are formed by a simulation using a finite element method;
a step CSP2 of measuring positions of the depressions formed;
a step CSP3 of comparing an amount of displacement D^{P} of each of the depressions obtained based on the strain distribution obtained in the step CSP1 with an amount of displacement D^{M} of each of the depressions obtained from the positions of the depressions obtained in the step CSP2; and
a step CSP4 of obtaining a distribution in the xy plane of Lz⁰, among the initial parameters, so as to reduce a difference between the amount of displacement D^{P} and the amount of displacement D^{M} based on a comparison result obtained in the step CSP3.

13. The manufacturing method according to claim 10, wherein:
the step C, in the step CS, includes a step CSD of obtaining at least one of initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state; and
the step CSD further includes:
a step CSD1 of obtaining the strain distribution of the entire mask base when at least one dummy opening is formed outside the active region formation portion by a simulation using a finite element method;
a step CSD2 of measuring a position of the at least one dummy opening formed;
a step CSD3 of comparing an amount of displacement D^{Pd} of the at least one dummy opening obtained based on the strain distribution obtained in the step CSD1 with an amount of displacement D^{Md} of the at least one dummy opening obtained from the position of the at least one dummy opening obtained in the step CSD2; and
a step CSD4 of obtaining at least one of the initial parameters so as to reduce a difference between the amount of displacement D^{Pd} and the amount of displacement D^{Md} based on a comparison result obtained in the step CSD3.

14. The manufacturing method according to claim 12, wherein:
the step C, in the step CS, includes a step CSD of obtaining at least one of initial parameters (Young's modulus Yx⁰, Yy⁰, modulus of rigidity Gxy⁰, Poisson's ratio Pxy⁰, density ρ⁰, tension Tx⁰, Ty⁰, size Lx⁰, Ly⁰, Lz⁰) used for obtaining the strain distribution of the entire mask base of the initial state; and
the step CSD further includes:
a step CSD1 of obtaining the strain distribution of the entire mask base when at least one dummy opening is formed outside the active region formation portion by a simulation using a finite element method;
a step CSD2 of measuring a position of the at least one dummy opening formed;
a step CSD3 of comparing an amount of displacement D^{Pd} of the at least one dummy opening obtained based on the strain distribution obtained in the step CSD1 with an amount of displacement D^{Md} of the at least one dummy opening obtained from the position of the at least one dummy opening obtained in the step CSD2; and
a step CSD4 of obtaining at least one of the initial parameters so as to reduce a difference between the amount of displacement D^{Pd} and the amount of displacement D^{Md} based on a comparison result obtained in the step CSD3.

15. The manufacturing method according to claim 9, wherein the mask base is formed of a magnetic metal layer.

16. The manufacturing method according to claim 9, wherein the mask base is formed of a resin layer.

17. The manufacturing method according to claim 16, wherein the deposition mask further includes a magnetic metal layer having at least one through hole through which the plurality of openings formed in the resin layer are exposed.
